(19) United States
(12) Patent Application Publication
(10) Pub. No.: US 2016/0118228 A1
(43) Pub. Date: Apr. 28, 2016

(54) THERMAL SPRAYING METHOD AND DEVICE THEREFOR

(71) Applicant: MAHLE International GmbH, Stuttgart (DE)

(72) Inventors: Peter ENGLERT, Bad Friedrichshall (DE); Oliver MAMBER, Markgroningen (DE); Ingo TRAUTWEIN, Bietigheim-Bissingen (DE); Tomas RODRIGUEZ, Stuttgart (DE)

(73) Assignee: MAHLE INTERNATIONAL GMBH, Stuttgart (DE)

(21) Appl. No.: 14/922,243

(22) Filed: Oct. 26, 2015

(30) Foreign Application Priority Data
Oct. 24, 2014 (DE) 10 2014 221 735.0

(51) Int. Cl. H01J 37/32; B05B 7/22; C23C 4/12

(52) U.S. Cl. CPC H01J 37/32376; C23C 4/127; B05B 7/22; H01J 37/3277; H01J 37/32798; H01J 2237/332

(57) ABSTRACT

The invention relates to a thermal spraying method, in particular for coating a surface by means of a plasma beam, using a shaped plasma beam, wherein a first plasma beam by means of at least one second plasma beam is controlled and/or shaped, wherein the second plasma beam at least partially and at least temporarily penetrates the first plasma beam.

### TECHNICAL FIELD

The invention relates to a thermal spraying method and to a device for thermal spraying, for coating a surface by means of a shaped plasma beam. In particular, the invention also relates to the application of such a method.

### PRIOR ART

Thermal spraying methods are suitable for coating surfaces. Thereby, additional materials, the so-called spraying additives, are melted or fused within or outside a jet burner, accelerated in the form of jet particles in a gas stream, and propelled onto the surface of the component to be coated. As opposed to overlay welding, the component surface here is not melted and is thermally stressed to only a slight extent. The forming of layers takes place because, depending on the process and the material, the jet particles when impacting on the component surface are more or less flattened, adhere mainly due to mechanical interlocking, and build up the sprayed layer in tiers. A plasma beam is inter alia considered as the energy source for melting or fusing the spraying additive material in so-called plasma spraying. Such a method is disclosed in EP 1 871 921 A1.

A typical plasma beam is not spread out widely, but is rather configured to be narrow and taper toward a point. On account thereof, a correspondingly narrow stripe on a surface can only ever be coated. Moreover, injecting powders for coating, for example a flux powder when manufacturing brazed components, leads to inhomogeneity of the plasma beam and/or to impulses in the plasma beam and, in some instances, to a drop in the energy which is contained in the plasma. This leads to inadequate fusing of the powder in the plasma and, on account thereof, to insufficient adherence on a metal surface to be coated.

Moreover, if and when a thin metal strip running at a fast speed of 20 to 300 m/min is coated by way of a thermal spraying method, in particular by way of a plasma spraying method, the plasma jet is often deformed in the running direction of the strip. If coating of the strip here is carried out in a high-energy plasma coating installation with outputs of more than 20 kW in order for the abovementioned energetic variations to be compensated for, the kinetic energy will rapidly rise to a level such that damage to or deformation of the thin metal strips may occur.

Control of the plasma jet and thus also the potential for shaping the plasma jet according to the prior art is implemented with the aid of strong magnetic fields, or by blowing using gases or compressed air. High magnetic field forces are already required even for small plasma jet geometries. The electric generators required therefor for generating the required current ratings for generating the magnetic field are cost intensive and in energetic terms not constructive.

It has also been demonstrated in experiments that no significant influence on a plasma jet may be achieved using the available magnetic field forces. Proprietary research has furthermore demonstrated that a plasma beam behaves like a very highly viscous liquid; therefore, adequate influence cannot be exerted using a low-viscosity medium such as compressed air.

### PRESENTATION OF THE INVENTION, OBJECT, SOLUTION, ADVANTAGES

It is the object of the invention to provide a thermal spraying method having a plasma beam in which the abovementioned disadvantages may as far as possible be reduced or avoided. It is also the object to provide a device for carrying out a thermal spraying method, by means of which an improved thermal spraying method is able to be carried out.

This object is achieved by a thermal spraying method, or a device, respectively, having the features of claim 1, or of claim 7 or 12, respectively. Advantageous refinements of the invention are derived from the dependent claims.

One exemplary embodiment of the present invention relates to a thermal spraying method for coating a surface by means of a plasma beam, wherein a first plasma beam by means of at least one second plasma beam is unified and/or shaped to form the plasma beam, wherein the second plasma beam at least partially and at least temporarily penetrates the first plasma beam.

In the present context, a plasma beam or else a plasma jet is to be understood to be a streaming gas or a gas mixture which by way of supplied energy is at least partially ionized. The supply of energy here is preferably performed in an electromagnetic fashion, that is to say, for example, with the aid of a high-frequency alternating current which heats the gas by way of induction. Other possibilities of supplying energy include, for example, excitement by ultraviolet light, other ionizing beams, by way of electric arcs, and/or by gas discharges. Such plasma typically is not in a thermal equilibrium, since the electrons in plasma regularly have a far greater energy than the ions. However, in the case of technically established low-pressure plasmas the degree of ionization is at maximum in the range of a few per mills.

In the concept of the present invention, two plasma beams at least partially and at least temporarily are mutually penetrated, when the particles which constitute the two plasma beams are at least partially mutually mixed and/or unified to form a common plasma.

It is preferable for the plasma beam resulting from the first plasma beam and from the second plasma beam, compared with the first and the second plasma beam, to have a wider and more homogenous plasma jet.

It is advantageous here for the at least one second plasma beam in relation to the first plasma beam to be aligned at a predefinable angle, wherein the angle will be unequal to 0 or 180°.

It is also preferable for the at least one second plasma beam in relation to the first plasma beam to be aligned at a predefinable angle between 15 and 45 degrees. According to experience, good control and/or shaping of the plasma beam is enabled in this way. Other alignments of the plasma beams may be likewise advantageous in certain applications.

It is preferable here for the at least one second plasma beam not to be aligned so as to be parallel with the first plasma beam. The alignment of a plasma beam here is to be understood to be the direction of the mean velocity vector of the streaming particles.

In order for a coating on a surface to be generated, it is preferable for a coating powder to be added to the first plasma beam. The first plasma beam is controlled and/or shaped with the aid of at least one second plasma beam, wherein the second plasma beam at least partially and at least temporarily penetrates the first plasma beam. On account thereof, the plasma beam is shaped while the coating powder is added.

According to the invention it is advantageous for the surface to be to a surface of a running strip, and for the second plasma beam to be aligned counter to the running direction of the running strip to be coated. This leads to deflection of the first plasma beam by the running strip being at least partially avoided, reduced, or eliminated. The unified plasma beam is then deflected at least less than the first plasma beam.

In one other exemplary embodiment the invention relates to a device for carrying out a thermal spraying method by means of a plasma beam, having a first source for a first plasma beam, characterized by a second source for a second plasma beam, which second source is disposable in such a manner that the second plasma beam at least partially and at least temporarily penetrates the first plasma beam such that the plasma beam is generatable on account thereof.

It is preferable here for the at least one second plasma beam in relation to the first plasma beam to be alignable at a predefinable angle, wherein the angle is unequal to 0 or 180°.

It is also advantageous for the at least one second plasma beam in relation to the first plasma beam to be alignable at an angle between 15 and 45 degrees.

In one further exemplary embodiment it is also advantageous for a powder supply for supplying to the first plasma beam a powder which is provided for coating to be provided.

It is likewise advantageous for the surface to be the surface of a running strip to be coated, and for the second plasma beam to be alignable counter to the running direction of the strip.

In one further exemplary embodiment according to the invention a device for controlling or regulating the adjustment of a first source and of a second source for generating a plasma beam is provided, in which device adjustment of the first source and/or of the second source is performed in such a manner that one plasma beam of a first plasma beam of the first source and of a second plasma beam of the second source, which has predefinable properties, in particular in terms of width and homogeneity, results.

Further advantageous design embodiments are described by the following description of the figures and by the dependent claims.

### BRIEF DESCRIPTION OF THE FIGURES OF THE DRAWING

The invention will be explained in more detail hereunder on the basis of at least one exemplary embodiment by means of the figures of the drawing, in which:

FIG. 1 shows a schematic illustration of a preferred exemplary embodiment of a device according to the invention; and

FIG. 2 shows a schematic illustration of a further exemplary embodiment.

### PREFERRED EMBODIMENT OF THE INVENTION

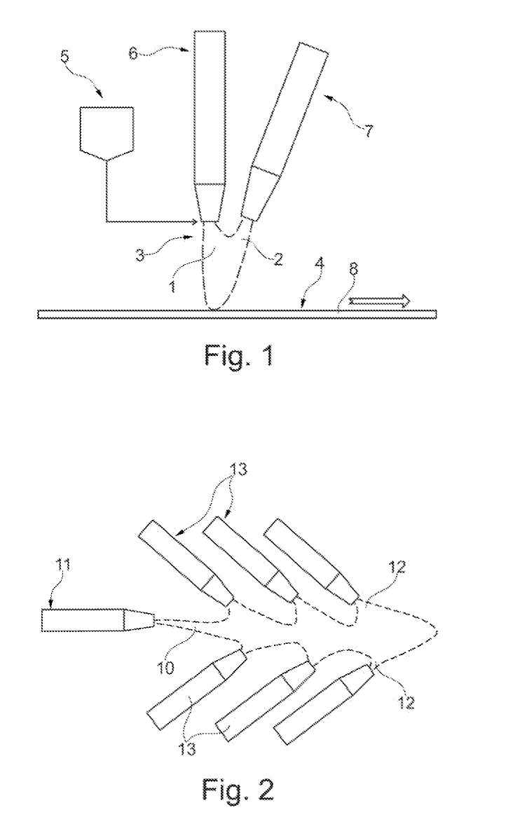

FIG. 1 shows a first source 6 of a first plasma beam 1, preferably a so-called plasma burner 1, and a second source 7 of a second plasma beam 2, preferably a further second plasma burner, the plasma beams 1, 2 of said burners being unified to form a merged or common plasma beam 3. A powder with which the surface 4 of a strip 8 running toward the right is to be coated is supplied to the first plasma beam 1 by way of a powder supply 5. The strip 8 is preferably a metal strip.

It has been able to be demonstrated in an experimental manner that the first plasma beam 1 can be influenced, in particular shaped and/or controlled, by a second plasma beam 2, and that hereby both beams 1, 2, which are also referred to as plasma jets, are homogenously unified to form a common plasma beam 3. The first plasma beam 1 may be formed, controlled, and/or geometrically modified by a laterally disposed second plasma beam 2.

Interestingly, two mutually intersecting plasma jets 1, 2 are not atomized, as is known in the case of two mutually intersecting beams of liquids, but they are unified to form one wider and more homogenous plasma jet 3. This effect now offers the possibility of implementing plasma powder coating in a significantly improved manner.

In one preferred embodiment a coating powder 5 is added to a first plasma beam 1. A second plasma beam 2 is now laterally supplied to this first plasma beam 1 at an angle which is preferably between 15 and 45 degrees. This results in a homogenous unification 3 of the two plasma beams 1, 2.

This new doubled plasma beam 3 now is significantly more homogenous and wider than the original beams on their own, which have been supplied with the coating powder 5. It has been demonstrated that, on account thereof, the spraying powder is applied onto the surface 4 in a more homogenous manner. The resultant wider plasma beam 3 leads to a wider coated surface.

If the second plasma beam 2 is now applied counter to the running direction of a fast-running metal strip to be coated, the plasma beam can be prevented from following the running direction of the strip. For coating a fast-running metal strip it is now possible for a large amount of powder to be added to a first plasma beam 1. On account thereof, the plasma beam 1 does indeed first become more inhomogeneous and more unstable, however, by way of one or a plurality of laterally disposed driving plasma beams 2 there is so much energy being supplied to this first powder plasma beam 1 that the powder remains melted for longer in the entire beam 3.

The entire beam 3 now holds more thermal energy, is more homogenous, and generates a significantly more homogenous coating result. At the same time, a plasma beam 3 which has been combined in this way permits a higher throughput of powder and enables a wider coated surface.

However, there is less kinetic energy than in a comparable high-energy (>20 kW) plasma coating system. A merged plasma jet 3 having a higher content of thermal energy but having less kinetic energy may thus be generated. The spacing of the unified plasma beam 3 from the strip surface 4 may thus be increased, on account of which electric flashovers and damage on the strip surface may now be precluded or largely avoided.

Embodiments of a method according to the invention and/or of a device according to the invention are advantageously suitable for coating components, in particular aluminum components, with a flux powder for brazing.

So-called flux agents are mainly employed in brazing of aluminum components, in particular of aluminum heat exchangers. Special fluoride-containing flux agents which are marketed under the trade name NOCOLOK have established themselves as the technology which is primarily used for this brazing method.

This flux agent melts just in front of the solder, cleans the surfaces to be brazed, and produces a metallically bright surface as required by the liquid solder in order for the latter to wet and bond. In many applications, the remnants of flux agents resulting therefrom may remain on the component, since they have no damaging effect, in particular no corrosive effect, on the materials used.

However, experience and research show that the coolant fluids may be disadvantageously influenced by flux remnants, on the one hand, and cross-sectional reductions caused by flux remnants may occur in pipes which for reasons of construction have narrow cross sections, on the other hand. Therefore, it is desirable for the addition of flux agents to be minimized. It would be ideal for the flux agents to be applied in a targeted manner exclusively on the locations to be brazed. This is made possible by the present invention.

FIG. 2 shows how a plasma beam 10 of a plasma source 11 is controlled by means of a plurality of other plasma beams 12 of other plasma sources 13.

1. Thermal spraying method for coating a surface by means of a plasma beam, wherein a first plasma beam by means of at least one second plasma beam is unified and/or shaped to form the plasma beam, wherein the second plasma beam at least partially and at least temporarily penetrates the first plasma beam.

2. Thermal spraying method according to claim 1, wherein the plasma beam resulting from the first plasma beam and from the second plasma beam, compared with the first and the second plasma beam, has a wider and more homogenous plasma jet.

3. Thermal spraying method according to claim 1, wherein the at least one second plasma beam in relation to the first plasma beam is aligned at a predefinable angle, wherein the angle will be unequal to 0 or 180°.

4. Thermal spraying method according to claim 3, wherein the at least one second plasma beam in relation to the first plasma beam is aligned at a predefinable angle between 15 and 45 degrees.

5. Thermal spraying method according to claim 1, wherein a coating powder is added to the first plasma beam.

6. Thermal spraying method according to claim 4, wherein the surface is a surface of a running strip, and that the second plasma beam is aligned counter to the running direction of the running strip to be coated.

7. Device for carrying out a thermal spraying method by means of a plasma beam, having a first source for a first plasma beam, wherein a second source for a second plasma beam, which second source is disposable in such a manner that the second plasma beam at least partially and at least temporarily penetrates the first plasma beam such that the plasma beam is generatable on account thereof.

8. Device according to claim 7, wherein the at least one second plasma beam (2) in relation to the first plasma beam (1) is alignable at a predefinable angle, wherein the angle is unequal to 0 or 180°.

9. Device according to claim 8, wherein the at least one second plasma beam in relation to the first plasma beam is alignable at an angle between 15 and 45 degrees.

10. Device according to claim 7, wherein a powder supply for supplying to the first plasma beam a powder which is provided for coating.

11. Device according to claim 10, wherein the the surface is the surface of a running strip to be coated, and that the second plasma beam is alignable counter to the running direction of the strip.

12. Device for controlling or regulating the adjustment of a first source and of a second source, in particular according to claim 7, for generating a plasma beam, in which adjustment of the first source and/or of the second source is performed in such a manner that one plasma beam of a first plasma beam of the first source and of a second plasma beam of the second source, which has predefinable properties, in particular in terms of width and homogeneity, results.
